(19) United States
(12) Patent Application Publication
(10) Pub. No.: US 2009/0117689 A1
(43) Pub. Date: May 7, 2009

(54) PACKAGED INTEGRATED CIRCUITS

(75) Inventor: Jian Chen, Heist-op-den-erg (BE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Melexis NV Microelectronic Intergrated Systems, Ieper (BE)

(21) Appl. No.: 11/817,394

(22) PCT Filed: Mar. 3, 2006
(86) PCT No.: PCT/IB2006/000465

§ 371 Date: Jul. 15, 2008

(30) Foreign Application Priority Data
Mar. 3, 2005 (GB) 0504379.9

(51) Int. Cl. H01L 21/02

(52) U.S. Cl. 438/116; 438/113; 257/E21.002; 257/E21.602

(57) ABSTRACT

A packaged, optically active integrated circuit device is shown is manufactured by mounting the integrated circuit (201) onto a first part of a lead frame (206) using epoxy (209). Electrical connections (207) are made using conventional wire bonding techniques between the integrated circuit (201) and peripheral parts (205) of the lead frame (206). Optical adhesive (202) is dispensed onto the surface of the integrated circuit to surround the optically active element (208). A glass lid (203) is placed onto the surface of the integrated circuit (201) aligned with the optical adhesive (202). This provides a mounted and covered assembly. The mounted and covered assembly is placed in a mould tool having projection with a soft surface opposite to and in contact with the exposed surface of the glass lid (203). Mould compound (204) is injected into the mould tool to encapsulate the integrated circuit (201), the lead frame (206) and such parts of the glass lid (203) as are not in contact with the soft surface of the mould tool.

The present invention relates to a method of packaging integrated circuits and particularly to packaging integrated circuits for use in optical systems. Such optical systems may include optical sensors, optical applications e.g. camera systems and DVD systems.

A DVD is read by projecting a narrow beam of light onto the surface of the spinning disc and detecting variations in the intensity of the light beam reflected therefrom. The light beam is typically generated by an LED, VCSEL, or laser diode. The reflected light may be detected by a photodiode connected to additional amplification and processing circuitry. In many embodiments, the photodiode and/or the amplification and/or processing circuitry is implemented as a single integrated circuit. The single integrated circuit would normally be packaged.

A number of known packaging techniques have limitations which render them undesirable for the present application. One such method involves packaging the whole device in clear epoxy instead of conventional black plastic. This method is low cost but does provide problems with discoloration and scratching of the epoxy. Additionally, the higher coefficient of thermal expansion of the clear epoxy compared to the black puts the packaged circuitry under greater stress in response to temperature variations.

An alternative method involves using pre-moulded plastic or ceramic packages provided with a cavity through which light may pass to the photodiode. These packages are further supplied with a glass lid to be attached over the mouth of the cavity, for the protection of the photodiode. The glass lid is fitted once the circuitry is encapsulated within the pre-formed package. This method results in additional costs due to the number of parts and the extra assembly steps. Additionally, difficulties are encountered with sealing the glass to the package and with contamination or condensation within the cavity.

Another alternative is to place a gel blob over the photodiode before encapsulating the package, making sure that the mould tool (or a projection thereof) is in contact with the gel. This provides an aperture in the formed package. However, cleaning the gel from the cavity can be difficult and also leaves the silicon surface exposed to the atmosphere. Adding a glass lid for protection introduces additional costs and results in the other disadvantages discussed above.

A further alternative involves gluing a glass wafer onto the surface of a silicon wafer containing the photodiode and subsequently etching selectively to expose the connection pads and create separation channels enabling the individual die and their glass lids to be separated. This provides a high reliability package but has a relatively high cost and a relatively low yield.

It is therefore an object of the present invention to provide a method of packaging an integrated circuit that overcomes or alleviates the above problems.

According to the present invention there is proposed a method of manufacturing a packaged optically active integrated circuit comprising the steps of: providing an integrated circuit incorporating at least one optically active element; dispensing an adhesive on the surface of the integrated circuit around the or each optically active element; placing a transparent lid over the or each optically active element, the transparent lid aligned with the adhesive, so as to form a covered assembly; inserting the assembly into a cavity of a moulding tool ensuring that at least a projection of the moulding tool is in contact with a portion of the surface of the transparent lid; introducing a plastic mould compound into the cavity so as to encapsulate, within a package, the integrated circuit except for the portion of the transparent lid in contact with the projection; removing the assembly from the cavity, whereby there is an opening defined in the package through which light may pass to or from the optically active element.

This provides a method of packaging an optically active integrated circuit which overcomes or alleviates the above problems. In particular, mounting the lid onto the integrated circuit before encapsulation reduces the risk of particulate contamination during later assembly stages. Additionally, this method is relatively low cost.

As used herein, the term optically active element relates to any element operable to sense incident light and/or emit light. Furthermore, the terms optical, optically and light, as used herein, should be understood to refer to electromagnetic radiation in infrared and ultraviolet spectral regions in addition to the visible region of the electromagnetic spectrum.

The integrated circuit may be provided on a wafer, which may be a conventional CMOS wafer.

The transparent lid may be formed from glass. The adhesive may be an optical adhesive, adapted to be substantially transparent. The adhesive is preferably dispensed so as to substantially surround the optically active element or elements. If the adhesive is an optical adhesive, it may additionally or alternatively be dispensed directly onto the optically active element or elements. in such embodiments, by not having a void beneath the lid the risk of contamination or condensation is further reduced.

In embodiments wherein there is more than one optically active element, a separate lid can be provided for each element or a single lid can be provided for all the elements. It is also possible for two or more optically active elements to be provided under a single lid and for one or more other optically active elements to be provided under separate lids. Where separate lids are provided, separate projections of the mould tool may be provided for each lid. Additionally, where separate lids are provided glue may be dispensed separately around each optically active element or group of elements with a separate lid.

The lids may be placed over the or each optically active element using conventional pick and place techniques.

The method may incorporate the further steps of: mounting the integrated circuit on a lead frame; and making electrical connections between the integrated circuit and peripheral portions of the lead frame. These can take at any time before the assembly is encapsulated. The lead frame may be a standard lead frame adapted to mount a variety of different integrated circuits. Alternatively, the lead frame may be specially adapted for the particular integrated circuit to be encapsulated. In some embodiments, one or more integrated circuits can be mounted on the same lead frame and encapsulated in the same package. Additionally or alternatively, a plurality of integrated circuits mounted on separate lead frames may be electrically connected and may be encapsulated in a single package.

In one preferred embodiment, a plurality of like integrated circuits are provided in an array on a silicon wafer; adhesive is provided around the optically active element or element of each integrated circuit in the array; a transparent lid is provided over each integrated circuit in the array and then the individual integrated circuits are separated for encapsulation.

Preferably the projection of the mould tool has a soft surface. This prevents scratches or other damage occurring to the lid. Additionally, this helps to ensure that the surface of the projection remains in contact with the lid and thus ensures that the surface of the lid stays clear of mould compound. Preferably, so that this may be achieved, the lid is relatively thin and/or is placed relatively close to the optically active element such that the combined thickness of the covered assembly does not vary by an amount greater than that which can be accommodated by the soft surface of the mould tool. This also helps produce a thin or low profile package, which can be advantageous in some applications.

Using the above method, the same mould tool (e.g. flat mould for QFN type of packages) can be used for a number of different integrated circuit devices having lids of differing sizes and/or mounted in differing locations on said integrated circuits. This allows production of a number of different devices to take place with reduced tooling costs.

In order that the invention is clearly understood, specific embodiments are described further below, by way of example only, and with reference to the accompanying drawings, in which:

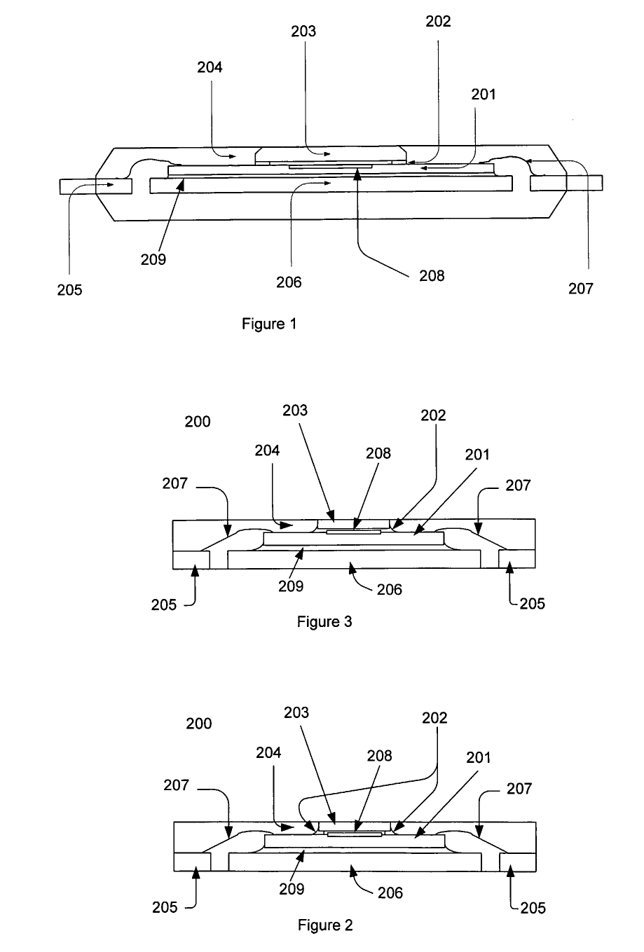

FIG. 1 shows a cross-sectional view of a packaged integrated circuit manufactured by the method of the present invention in a first package style;

FIG. 2 shows a cross-sectional view of a packaged integrated circuit manufactured by the method of the present invention in a second package style; and

FIG. 3 shows a cross-sectional view of a packaged integrated circuit manufactured by an alternative embodiment of the method of the present invention in the second package style;

Referring to FIG. 1, a packaged, optically active integrated circuit device is shown. The device comprises an integrated circuit 201 mounted on a lead frame 206. Electrical connections are provided between the integrated circuit and peripheral portions 205 of lead frame 206, to enable the integrated circuit 201 to be connected to external circuitry. A protective glass lid 203 is provided over an optically active element 208 of the integrated circuit 201. The optically active element 208 may comprise light emitting means and/or light sensing means, as desired or as appropriate. The lid 203 is maintained in position by adhesive 202 provided around the optically active element 208. For protection the whole device is encapsulated in a package 204.

The device is manufactured by the steps described below. Integrated circuit 201 is mounted onto a first part of a lead frame 206 using epoxy 209. Electrical connections 207 are made using conventional wire bonding techniques between the integrated circuit 201 and peripheral parts 205 of the lead frame 206. Optical adhesive 202 is dispensed onto the surface of the integrated circuit so as to substantially surround the optically active element 208. A glass lid 203 is placed onto the surface of the integrated circuit 201 aligned with the optical adhesive 202. This provides a mounted and covered assembly.

The integrated circuit 201 may typically be manufactured as one of an array of like integrated circuits on a wafer. A glass lid 203 may be placed over each integrated circuit 201 in the array before separation from the array or after it is separated from the array. If the glass lid 203 is provided after separation, it can be provided either before or after the integrated circuit 201 is mounted on the lead frame 206.

The mounted and covered assembly is placed in a mould tool having projection with a soft surface opposite to and in contact with the exposed surface of the glass lid 203. Mould compound 204 is injected into the mould tool to encapsulate the integrated circuit 201, the lead frame 206 and such parts of the glass lid 203 as are not in contact with the soft surface of the mould tool.

Mounting the glass lid directly onto the surface of the silicon prior to encapsulation according to the method of the present invention reduces the risk of particulate contamination during later assembly stages. Additionally, it enables the use of a single multi cavity mould tool for a plurality of different integrated circuits thus reducing costs and making specialised integrated circuits cost effective at lower volumes. A further advantage of the method of the present invention is that it can produce a thin (low profile) package with the optically active elements in well defined positions relative to the surface of the glass lid.

FIG. 2 shows an implementation of an optically active integrated circuit device in a low profile package type designed for direct surface mounting onto a substrate or circuit board. The smaller package type may be manufactured according to the same method described above. FIG. 3 shows another low profile package wherein the optical glue 202 has been dispensed to cover the entire area of the optically sensitive area 208. This arrangement can reduce still further the risk of contamination or condensation since it avoids the creation of a void below the glass lid 203. This arrangement can, of course, be applied to the implementation shown in FIG. 1, if required or if desired.

It is of course to be understood that the invention is not to be restricted to the details of the above embodiment which is described by way of example only.

1. A method of manufacturing a packaged optically active integrated circuit comprising the steps of:
providing an integrated circuit incorporating at least one optically active element;
dispensing an adhesive on the surface of the integrated circuit around each optically active element;
placing a transparent lid over each optically active element, the transparent lid aligned with the adhesive, so as to form a covered assembly;
inserting the assembly into a cavity of a moulding tool ensuring that at least a projection of the moulding tool is in contact with a portion of the surface of the transparent lid;
introducing a plastic mould compound into the cavity so as to encapsulate, within a package, the integrated circuit except for the portion of the transparent lid in contact with the projection;
removing the assembly from the cavity, whereby there is an opening defined in the package through which light may pass to or from the optically active element.

2. A method as claimed in claim 1 wherein the projection of the mould tool has a soft surface.

3. A method as claimed in claim 1 wherein the lid is relatively thin such that the combined thickness of the covered assembly does not vary by an amount greater than that which can be accommodated by the soft surface of the mould tool.

4. A method as claimed in claim 1 wherein the lid is placed relatively close to the optically active element such that the combined thickness of the covered assembly does not vary by an amount greater than that which can be accommodated by the soft surface of the mould tool.

5. A method as claimed in claim 1 wherein integrated circuit is provided on a conventional CMOS wafer.

6. A method as claimed in claim 1 wherein the transparent lid is formed from glass.

7. A method as claimed in claim 1 wherein the adhesive is preferably dispensed so as to substantially surround the optically active element or elements.

8. A method as claimed in claim 1 wherein the adhesive is an optical adhesive.

9. A method as claimed in claim 8 wherein the adhesive is dispensed directly onto the optically active element or elements.

10. A method as claimed in claim 1 wherein if there is more than one optically active element in the integrated circuit a single lid is provided for all the optically active elements.

11. A method as claimed in claim 1 wherein if there is more than one optically active element in the integrated circuit separate lids are provided for each optically active element.

12. A method as claimed in claim 11 wherein separate projections of the mould tool may be provided for each lid.

13. A method as claimed in claim 11 wherein each lid is placed over the optically active element or elements using conventional pick and place techniques.

14. A method as claimed in claim 1 further including the steps of:
mounting the integrated circuit on a lead frame; and
making electrical connections between the integrated circuit and peripheral portions of the lead frame.

15. A method as claimed in claim 1 wherein one or more integrated circuits are mounted on the same lead frame and encapsulated in the same package.

16. A method as claimed in claim 1 wherein a plurality of integrated circuits mounted on separate lead frames are electrically connected and encapsulated in a single package.

17. A method as claimed in claim 1 wherein:
a plurality of like integrated circuits are provided in an array on a silicon wafer;
adhesive is provided around the optically active element or elements of each integrated circuit in the array;
a transparent lid is provided over each integrated circuit in the array; and then the individual integrated circuits are separated for encapsulation.
